(19) United States
(12) Patent Application Publication
(10) Pub. No.: US 2010/0241911 A1
(43) Pub. Date: Sep. 23, 2010

(54) ADDRESS GENERATOR OF COMMUNICATION DATA INTERLEAVER AND COMMUNICATION DATA DECODING CIRCUIT

(75) Inventors: Yun-Yi Shih, Tainan County (TW); Chun-Yu Chen, Taipei County (TW); Cheng-Hung Lin, Taipei County (TW); An-Yu Wu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Industrial Technology Research Institute, Hsinchu (TW)

(21) Appl. No.: 12/419,272

(22) Filed: Apr. 6, 2009

(30) Foreign Application Priority Data
Mar. 20, 2009 (TW) 98109173

(51) Int. Cl. G11C 29/00; G06F 11/00

(52) U.S. Cl. 714/702; 714/E11.001

(57) ABSTRACT

An address generator of a communication data interleaver and a communication data decoding circuit are provided. The address generator includes a first operation unit and a second operation unit. The first operation unit receives a first parameter and a first operation result. The first operation unit performs a recursive operation according to the first parameter and the first operation result and outputs the first operation result. The second operation unit receives the first operation result, a second operation result, and a second parameter. According to a transmission mode signal, whether the second operation unit generates a second operation result is determined by performing a recursive operation according to the first operation result, the second parameter, and the second operation result, or by calculating the first operation result and the second parameter.

### CROSS-REFERENCE TO RELATED APPLICATION

This application claims the priority benefit of Taiwan application serial no. 98109173, filed on Mar. 20, 2009. The entirety the above-mentioned patent application is hereby incorporated by reference herein and made a part of specification.

### BACKGROUND OF THE INVENTION

1. Field of the Invention

The present invention relates to an address generator. More particularly, the present invention relates to a communication data decoding circuit and an address generator of a communication data interleaver integrated with a plurality of communication protocol operation units.

2. Description of Related Art

With development of technology, communication between people becomes more convenient. To cope with different demands such as an environment demand, a speed demand, and a market demand, a plurality of communication protocol standards is developed. Therefore, a general developing trend of a present communication system is to integrate the communication protocol standards into a single apparatus, even though integration of the communication protocol standards often increases a hardware size. Increasing utilization rates of various modules in the communication system is an important key to reduce the hardware size of the communication device when the multiple communication protocol standards are applied. As for a present communication technique, if a plurality of independent communication modules is fabricated according to the multiple communication protocol standards, the hardware size of such a communication device is considerable.

An interleaver is an important device in the communication system. By combining the interleaver with a encoder/decoder, an error correcting capability of the communication system can be improved. Since the interleaver probably stores data in a table and then interleaves data, the interleaver possibly occupies a certain area of the hardware. Moreover, since different communication protocol standards generally require different interleavers, when multiple interleavers corresponding to different communication protocol standards are used in the communication system, the hardware size of the communication system is greatly increased.

### SUMMARY OF THE INVENTION

The present invention is directed to an address generator of a communication data interleaver which can integrate operation units used in different transmission modes.

The present invention is directed to a communication data decoding circuit which can integrate data of a plurality of memory banks corresponding to a plurality of decoders into one memory bank.

The present invention provides an address generator of a communication data interleaver. The address generator includes a first operation unit and a second operation unit. The first operation unit has a first input terminal, a second input terminal, and an output terminal. The first input terminal of the first operation unit receives a first parameter, and the second input terminal of the first operation unit is coupled to the output terminal of the first operation unit. The first operation unit performs a recursive operation according to the first parameter and a first operation result and outputs the first operation result through the output terminal. The second operation unit has a first input terminal, a second input terminal, a third input terminal, and an output terminal. The first input terminal of the second operation unit is coupled to the output terminal of the first operation unit, the second input terminal of the second operation unit receives a second parameter, and the third input terminal of the second operation unit is coupled to the output terminal of the second operation unit. According to a transmission mode signal, it is determined whether the second operation unit generates a second operation result by performing a recursive operation according to the first operation result, the second parameter, and the second operation result, or by calculating the first operation result and the second parameter.

The present invention provides a communication data coding/decoding circuit including a first address generator, a memory bank, and a first data decoder. The first address generator includes a first operation unit and a second operation unit. The first operation unit has a first input terminal, a second input terminal, and an output terminal. The first input terminal of the first operation unit receives a first parameter, and the second input terminal of the first operation unit is coupled to the output terminal of the first operation unit. The first operation unit performs a recursive operation according to the first parameter and outputs a first operation result. The second operation unit has a first input terminal, a second input terminal, a third input terminal, and an output terminal. The first input terminal of the second operation unit is coupled to the output terminal of the first operation unit, the second input terminal of the second operation unit receives a second parameter, and the third input terminal of the second operation unit is coupled to the output terminal of the second operation unit. According to a transmission mode signal, it is determined whether the second operation unit generates a second operation result by performing a recursive operation according to the first operation result, the second parameter, and the second operation result, or by calculating the first operation result and the second parameter. The memory bank is coupled to the first address generator and is used for outputting data to be decoded according to the second operation result. The first data decoder is coupled to the memory bank for decoding the data to be decoded.

The present invention provides a communication data decoding circuit including a plurality of first address generators, a first address decoder, a memory bank, and a plurality of data decoders. Each of the first address generators receives a first parameter and a second parameter and determines whether to generate a second operation result by performing a recursive operation according to the first parameter, or by calculating the first parameter and the second parameter according to a transmission mode signal. The first address decoder is coupled to the first address generators for generating a first address and a first vector address corresponding signal according to a plurality of the second operation results. The memory bank is coupled to the first address decoder and is used for outputting data to be decoded according to the first address and the first vector address corresponding signal, wherein the data to be decoded has a plurality of data segments. The data decoders are coupled to the memory bank, and the data decoders respectively capture the corresponding data segment in the data to be decoded according to the first vector address corresponding signal, so as to decode the captured data segment.

Accordingly, the operation units and the data decoders used in different transmission modes are integrated into the address generator of the communication data interleaver and the communication data decoding circuit of the present invention. Moreover, in case of proper degree of parallelism, the to-be-decoded data in the memory banks is integrated into a signal memory bank.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic system diagram of a communication data coding circuit according to an embodiment of the present invention.

FIG. 1B is a circuit diagram illustrating a memory coupled to an address generator of an interleaver of FIG. 1A.

FIG. 1C is a system block diagram illustrating an address generator of a communication data interleaver according to an embodiment of the present invention.

FIG. 2 is a circuit diagram illustrating an address generator of a communication data interleaver of FIG. 1C.

FIG. 3 is a circuit diagram of a remainder operator 112 of FIG. 2.

FIG. 4 is a system block diagram of a communication data coding/decoding circuit according to an embodiment of the present invention.

FIG. 5 is a system block diagram of a communication data decoding circuit integrated with single binary and double binary according to an embodiment of the present invention.

FIG. 6 is a system block diagram of a communication data decoding circuit according to another embodiment of the present invention.

FIG. 7 is a schematic diagram illustrating a data configuration of a memory bank.

FIG. 8 is a schematic diagram illustrating data segments captured by data decoders of FIG. 6.

### DESCRIPTION OF EMBODIMENTS

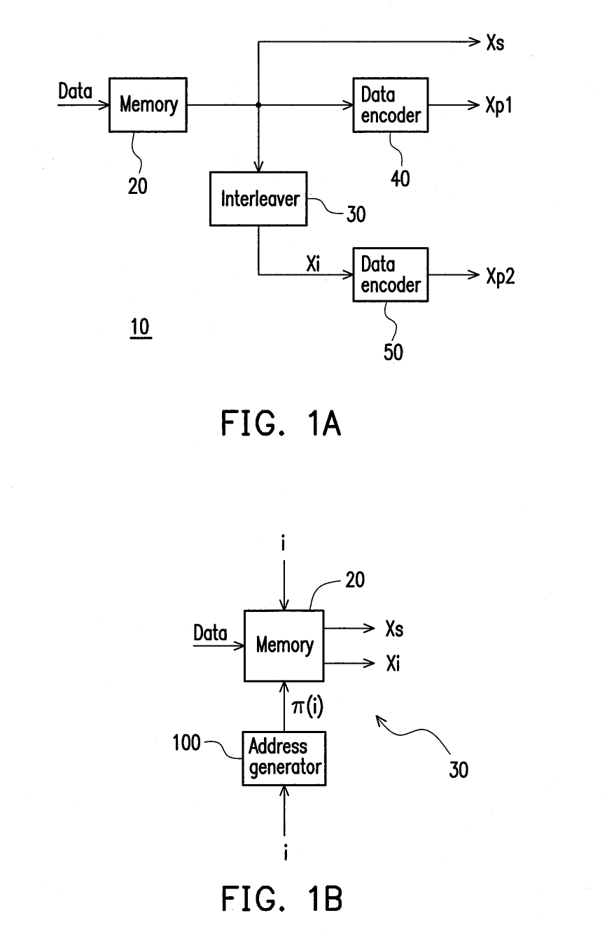

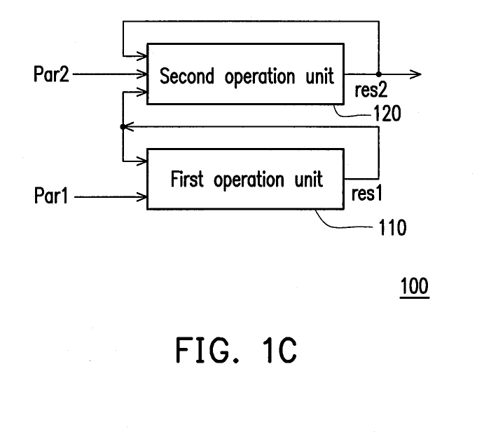

FIG. 1A is a system schematic diagram of a communication data coding circuit according to an embodiment of the present invention. Referring to FIG. 1A, in the communication data coding circuit 10, a memory 20 receives and stores an input data Data and sequentially outputs the stored data as a communication signal Xs. A data encoder 40 codes the communication signal Xs and outputs a communication signal Xp1. An interleaver 30 interleaves the communication signal Xs and outputs an interleaved communication signal Xi. A data encoder 40 codes the interleaved communication signal Xi and outputs a communication signal Xp2.

FIG. 1B is a circuit diagram illustrating a memory coupled to an address generator of an interleaver of FIG. 1A. Referring to FIG. 1B, if the memory 20 receives an incremental original address i, the memory 20 outputs the communication signal Xs. By contrast, if the memory 20 receives an interleaved address II(i) output from an address generator 100 in the interleaver 30, the memory 20 then outputs the communication signal Xi. Here, a data interleaving function of the interleaver 30 can be achieved by combining the memory 20 and the address generator 100.

FIG. 1C is a system block diagram illustrating an address generator of a communication data interleaver according to an embodiment of the present invention. Referring to FIG. 1C, the address generator 100 includes a first operation unit 110 and a second operation unit 120. A first input terminal of the first operation unit 110 receives a first parameter par1, and a second input terminal of the first operation unit 110 is coupled to an output terminal of the first operation unit 110. The first operation unit 110 performs a recursive operation according to the first parameter par1 and a first operation result res1 and outputs the first operation result res1 through the output terminal. A first input terminal of the second operation unit 120 is coupled to the output terminal of the first operation unit 110, a second input terminal of the second operation unit 120 receives a second parameter par2, and a third input terminal of the second operation unit 120 is coupled to an output terminal of the second operation unit 120. According to a transmission mode signal, it is determined whether the second operation unit 120 generates a second operation result res2 by performing a recursive operation according to the first operation result res1, the second parameter par2, and the second operation result res2, or by calculating the first operation result res1 and the second parameter par2.

When the transmission mode signal represents a first mode (wherein the first mode is, for example, a 3GPP long term evolution (LTE) standard, and the LTE standard refers to single binary convolution turbo codes (CTC)), according to the LTE standard, the address generator of the interleaver generates the addresses according to a following quadratic polynomial:

For i=0: K−1

Π(i)=(f₁·i+f₂·i²)mod K (1)

end

wherein i represents an original address, II(i) represents an interleaved address which is output by the address generator 100 and corresponds to the original address, and f₁ and f₂ are determined by a block size K which can be obtained by looking up a table 1, wherein the block is, for example, a forward error correction (FEC) block. In the table 1, there are 17 FEC block sizes K listed for reference. In a LTE standard document, there are totally 188 FEC block sizes, and “Mode” indicated in the table 1 represents modes of the block sizes, which is different from the first mode of the transmission mode signal.

TABLE 1

| Mode | K | f1 | f2 |
|---|---|---|---|
| 1 | 48 | 7 | 12 |
| 2 | 72 | 7 | 18 |
| 3 | 96 | 11 | 24 |
| 4 | 144 | 17 | 108 |
| 5 | 192 | 23 | 48 |
| 6 | 216 | 11 | 36 |
| 7 | 240 | 29 | 60 |
| 8 | 288 | 19 | 36 |
| 9 | 360 | 133 | 90 |
| 10 | 384 | 23 | 48 |
| 11 | 432 | 47 | 72 |
| 12 | 480 | 89 | 180 |
| 13 | 960 | 29 | 60 |
| 14 | 1920 | 31 | 120 |
| 15 | 2880 | 29 | 300 |
| 16 | 3840 | 331 | 120 |
| 17 | 4800 | 71 | 120 |

A recursive formula can be deduced from the equation (1) of the address generator of the LTE standard, and a deduction process thereof is as follows:

$$\begin{matrix}Π ( i + 1 ) = [ {f}_{1} \cdot ( i + 1 ) - {f}_{2} \cdot {( i + 1 )}^{2} ] mod K \\ = [ Π ( i ) + ( {f}_{1} + {f}_{2} + 2 \cdot {f}_{2} \cdot i ) ] mod K\end{matrix} \\ wherein if a function H ( i ) = ( {f}_{1} + {f}_{2} + 2 \cdot {f}_{2} \cdot i ) , then \text{:} \\ = [ Π ( i ) + H ( i ) ] mod K \qquad ( 2 )$$

and another recursive formula can also be deduced from the function H(i), and a deduction process thereof is as follows:

$$\begin{matrix}H ( i + 1 ) = [ {f}_{1} + {f}_{2} + 2 \cdot {f}_{2} \cdot ( i + 1 ) ] mod K \\ = [ H ( i ) + 2 {f}_{2} ] mod K\end{matrix} \qquad ( 3 )$$

Here, an initial value of the recursive function H(i) is H(0)=f₁+f₂, and an initial value of the recursive function II(i) is II(0)=0. Accordingly, when the transmission mode signal represents the first mode, the first operation unit 110 performs the recursive operation according to the equation (3), wherein H(i) represents an i-th first operation result res1, f₂ represents the first parameter par1, K is a constant, and mod is a remainder operator. Values of the aforementioned K, f₁ and f₂ can be obtained from the table 1. The recursive operation performed by the second operation unit 120 is the equation (2), wherein II(i) represents an i-th second operation result res2.

When the transmission mode signal represents a second mode (the second mode is, for example, a worldwide interoperability for microwave access (WiMAX) standard, and the WiMAX standard is double binary CTC), according to the WiMAX 802.16e standard, the address generator of the interleaver generates the addresses according to following equations:

For i=0: K−1
switch i mod 4:

case 0: Π(i)=(P0·i+1)mod K (4)

case 1: Π(i)=(P0·i+1+K/2+P1)mod K (5)

case 2: Π(i)=(P0·i+1+P2)mod K (6)

case 3: Π(i)=(P0·i+1+K/2+P3)mod K (7)

end

wherein, i represents the original address, II(i) represents the interleaved address which is output by the address generator 100 and corresponds to the original address, P0, P1, P2, and P3 are determined by an input byte number K, which can be obtained by looking up a table 2. Since the WiMAX standard applies the double binary CTC, the input byte number K in the table 2 is half the FEC block size.

TABLE 2

| Mode | K | P0 | P1 | P2 | P3 |
|---|---|---|---|---|---|
| 1 | 24 | 5 | 0 | 0 | 0 |
| 2 | 36 | 11 | 18 | 0 | 18 |
| 3 | 48 | 13 | 24 | 0 | 24 |
| 4 | 72 | 11 | 6 | 0 | 6 |
| 5 | 96 | 7 | 48 | 24 | 72 |
| 6 | 108 | 11 | 54 | 56 | 2 |
| 7 | 120 | 13 | 60 | 0 | 60 |
| 8 | 144 | 17 | 74 | 72 | 2 |
| 9 | 180 | 11 | 90 | 0 | 90 |
| 10 | 192 | 11 | 96 | 48 | 144 |
| 11 | 216 | 13 | 108 | 0 | 108 |
| 12 | 240 | 13 | 120 | 60 | 180 |
| 13 | 480 | 53 | 62 | 12 | 2 |
| 14 | 960 | 43 | 64 | 300 | 824 |
| 15 | 1440 | 43 | 720 | 360 | 540 |
| 16 | 1920 | 31 | 8 | 24 | 16 |
| 17 | 2400 | 53 | 66 | 24 | 2 |

If TP1=1+K/2+P1, TP2=1+P2, TP3=1+K/2+P3, and a function P(i)=P0·i, the equations (4)-(7) of the address generators of the WiMAX standard are then changed to:

For i=0: K−1
switch i mod 4:

case 0: Π(i)=(P(i)+1)mod K (8)

case 1: Π(i)=(P(i)+TP1)mod K (9)

case 2: Π(i)=(P(i)+TP2)mod K (10)

case 3: Π(i)=(P(i)+TP3)mod K (11)

end

wherein a following recursive equation can also be deduced from the function P(i)=P0*i:

P(i+1)=P(i)+P0 (12)

Accordingly, when the transmission mode signal represents the second mode, the first operation unit 110 performs the recursive operation according to the equation (12), wherein P(i) represent an i-th first operation result res1, and P0 is the first parameter. If i mod 4=0, the second operation unit 120 then performs the operation according to the equation (8), wherein II(i) represents an i-th second operation result res2, K is a constant, and mod is a remainder operator. If i mod 4=1, the second operation unit 120 then performs the operation according to the equation (9), wherein the second parameter TP1=1+K/2+P1, and K and P1 are constants. If i mod 4=2, the second operation unit 120 then performs the operation according to the equation (10), wherein the second parameter TP2=1+P2, and P2 is a constant. If i mod 4=3, the second operation unit 120 then performs the operation according to the equation (11), wherein the second parameter TP3=1+K/2+P3, and P3 is a constant. Values of the aforementioned K, P1, P2, and P3 can be obtained by looking up the table 2. Accordingly, when the transmission mode signal represents a different mode, the address generator can generate a corresponding second operation result according to the different mode, and the interleaver outputs interleaved data according to the second operation result for subsequent processing.

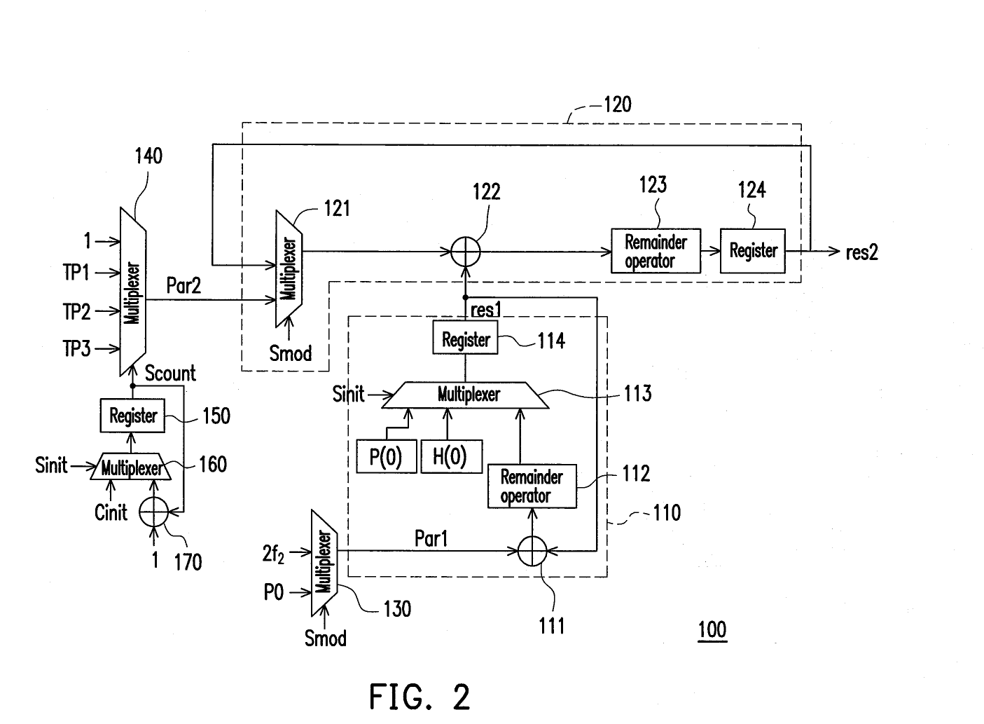

The operation equations of the first operation unit 110 and the second operation unit 120 can be integrated, and the aforementioned operations can be implemented by hardware. FIG. 2 is a circuit diagram illustrating the address generator of the communication data interleaver of FIG. 1C. Referring to FIG. 1C and FIG. 2, the first operation unit 110 includes an adder 111, a remainder operator 112, a multiplexer 113, and a temporary storage unit 114, wherein the temporary storage unit 114 is, for example, a register 114. A first input terminal of the adder 111 receives the first parameter par1, and a second input terminal of the adder 111 receives the first operation result res1. The remainder operator 112 is coupled to an output terminal of the adder 111 for performing a remainder operation with a divisor of K on an operation result of the adder 111. A first terminal of the multiplexer 113 is coupled to an output terminal of the remainder operator 112, and a second terminal of the multiplexer 113 receives initial values for outputting the initial values or an operation result of the remainder operator 112 according to an initial signal Sint, wherein the initial values are, for example, P(0) and H(0), which are described later. The register 114 stores an output of the multiplexer 113 and outputs the stored data as the first operation result res1.

The second operation unit 120 includes a multiplexer 121, an adder 122, a remainder operator 123, and a temporary storage unit 124, wherein the temporary storage unit 124 is, for example, a register 124. A first terminal of the multiplexer 121 receives the second operation result res2, and a second terminal of the multiplexer 121 receives the second parameter par2. The multiplexer 121 determines to output the second parameter par2 or the second operation result res2 according to a transmission mode signal Smod. A first input terminal of the adder 122 is coupled to an output terminal of the multiplexer 121, and a second input terminal of the adder 122 receives the first operation result res1. The remainder operator 123 is coupled to an output terminal of the adder 122 to perform a remainder operation with a divisor of K on an operation result of the adder 122, so as to output an operation result, wherein K is obtained from the table 1 or the table 2 according to the transmission mode signal Smod. The register 124 is coupled to the remainder operator 123 for temporarily storing the output of the remainder operator 123 and outputting the stored data as the second operation result res2.

Moreover, the address generator 100 further includes multiplexers 130, 140, and 160, a register 150, and an adder 170. A first terminal of the multiplexer 130 receives a first reference value (for example, 2f₂), and a second terminal of the multiplexer 130 is coupled to a second reference value (for example, P0). The multiplexer 130 determines whether to output the first reference value or the second reference value as the first parameter par1 according to the transmission mode signal Smod. A first terminal of the multiplexer 140 receives a first predetermined value (for example, 1), a second terminal of the multiplexer 140 is coupled to a second predetermined value (for example, TP1), a third terminal of the multiplexer 140 is coupled to a third predetermined value (for example, TP2), and a fourth terminal of the multiplexer 140 is coupled to a fourth predetermined value (for example, TP3). The multiplexer 140 determines whether to output the first predetermined value, the second predetermined value, the third predetermined value, or the fourth predetermined value as the second parameter par2 according to a counting result Scount.

The adder 170 receives the value 1 and the counting result Scount. The multiplexer 160 is coupled to an output terminal of the adder 170 and receives a counting initial value Cinit, so as to determine whether to output an operation result of the adder 170 or the counting initial value Cinit according to whether the multiplexer 160 is initialized. The register 150 is coupled to the multiplexer 160 for temporarily storing an output of the multiplexer 160 and outputting the stored data as the counting result Scount. Here, the register 150, the multiplexer 160, and the adder 170 can be regarded as a counter, so as to output the counting initial value Cinit as the counting result Scount when the counter is initialized. Moreover, the counting result Scount can be sequentially accumulated. Taking FIG. 2 as an example, the counting result Scount is represented by 2 bits. If a value of the counting result Scount is 3, after the counting result Scount is accumulated by 1, the value of the counting result Scount is 0.

For example, when the transmission mode signal Smod represents the first mode, the multiplexer 113 first outputs the initial value H(0) according to the initial signal Sinit, and then the initial value H(0) serving as the first operation result res1 is output through the register 114. The first operation result res1 is then transmitted back to the adder 111. Thereafter, the multiplexer 130 outputs 2f₂ according to the transmission mode signal Smod. After the operations are performed by the adder 111 and the remainder operator 112, the multiplexer 113 outputs the operation result of the remainder operator 112 to the register 114 according to the initial signal Sinit, so that the first operation result res1 is (H(0)+2f₂) mod K, i.e. H(1)=[H(0)+2f₂] mod K. Then, after further operations are performed by the adder 111 and the remainder operator 112, the first operation result res1 is then (H(1)+2f₂) mod K, i.e. H(2)=[H(1)+2f₂] mod K. Accordingly, if the first operation unit 110 continually performs the operations, the equation (3): H(i+1)=[H(i)+2f₂] mod K is continually calculated.

Moreover, the multiplexer 121 outputs the second operation result res2 according to the transmission mode signal Smod, and before the adder 122 and the remainder operator 123 perform operations, the second operation result res2 is II(0). When the adder 122 receives the first operation result res1 (which is H(0)), and after the operations are performed by the adder 122 and the remainder operator 123, the second operation result res2 is [Π(0)+H(0)] mod K, i.e. Π(1)=[Π(0)+H(0)] mod K. Thereafter, after further operations are performed by the adder 122 and the remainder operator 123, the second operation result res2 is then [Π(1)+H(1)] mod K, i.e. H(2)=[Π(1)+H(1)] mod K. Accordingly, if the second operation unit 120 continually performs the operations, the equation (2): Π(i+1)=[[Π(i)+H(i)] mod K is continually calculated.

On the other hand, when the transmission mode signal Smod represents the second mode, the multiplexer 113 first outputs the initial value P(0) according to the initial signal Sinit, and then the initial value H(0) serving as the first operation result res1 is output through the register 114, and the first operation result res1 is transmitted back to the adder 111. Thereafter, the multiplexer 130 outputs P0 according to the transmission mode signal Smod. After the operations are performed by the adder 111 and the remainder operator 112, the multiplexer 113 outputs the operation result of the remainder operator 112 to the register 114 according to the initial signal Sinit, so that the first operation result res1 is (P(0)+P0) mod K, i.e. P(1)=[P(0)+P0] mod K. Next, after further operations are performed by the adder 111 and the remainder operator 112, the first operation result res1 is then [P(1)+P0] mod K, i.e. P(2)=[P(1)+P0] mod K. Accordingly, if the first operation unit 110 continually performs the operations, the equation (12): P(i+1)=[P(i)+P0] mod K is continually calculated.

Moreover, the multiplexer 121 outputs the second parameter par2 according to the transmission mode signal Smod, and before the adder 122 and the remainder operator 123 perform operations, the second operation result res2 is II(0). The counting result output from the counter formed by the register 150, the multiplexer 160, and the adder 170 is Scount. Moreover, the multiplexer 140 has four input terminals, and a binary signal capable of being received by a control terminal of the multiplexer 140 is “00”-“11”. In terms of digital logic, the multiplexer 140 has an operation function of obtaining a remainder of a value divided by 4. Therefore, the multiplexer 140, the register 150, the multiplexer 160, and the adder 170 may achieve a function of i mod 4, and the multiplexer 140 can select one of the first to the fourth predetermined values according to the remainder.

Accordingly, if the adder 122 and the remainder operator 123 perform the operations according to a third parameter and the first operation result res1, according to an operation sequence, the operation results are: Π(1)=[P(1)+TP1] mod K, Π(2)=[P(2)+TP2] mod K, Π(3)=[P(3)+TP3] mod K, Π(4)=[P(4)+1] mod K, and the rest can be deduced by analogy. Accordingly, the second operation unit 120 can implement the operation functions of the equations (8)-(11).

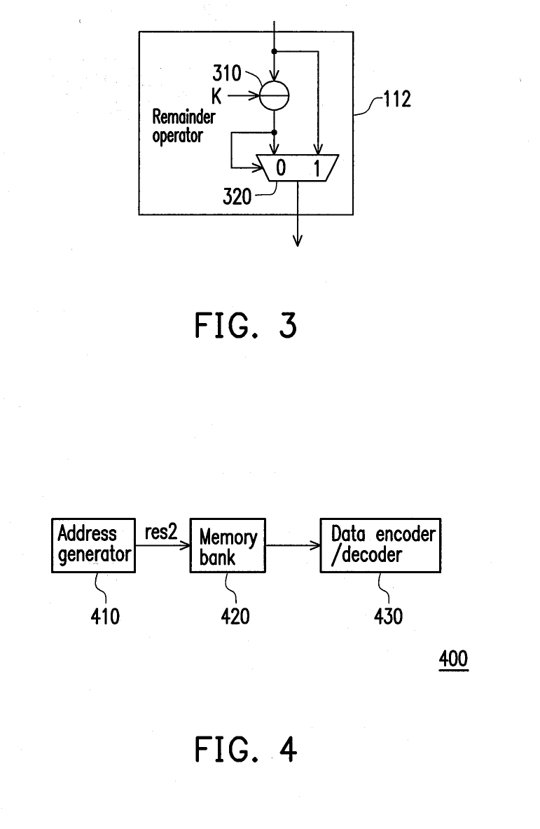

Next, implementation of the remainder operator is described below, and the remainder operator 112 is first taken as an example. FIG. 3 is a circuit diagram of the remainder operator 112 of FIG. 2. Referring to FIG. 2 and FIG. 3, the remainder operator 112 includes a subtractor 310 and a multiplexer 320. A first input terminal of the subtractor 310 is coupled to the output terminal of the adder 111, and a second input terminal of the subtractor 310 receives an operation value (for example, K) for subtracting the operation value from the operation result of the adder 111. A first terminal of the multiplexer 320 is coupled to the output terminal of the adder 111, a second terminal of the multiplexer 320 is coupled to an output terminal of the subtractor 310, and an output terminal of the multiplexer 320 is coupled to the first terminal of the multiplexer 113. Here, the operation value K can be obtained from the table 1 or the table 2 according to the transmission mode signal.

According to a complement of the binary, the multiplexer 320 can determine whether the operation result of the adder 111 is greater than the operation value according to a most significant bit (MSB) in the operation result of the subtractor 310. If the operation result of the adder 111 is greater than the operation value K, the multiplexer 320 outputs the operation result of the subtractor 310, while if the operation result of the adder 111 is less than the operation value K, the multiplexer 320 outputs the operation result of the adder 111. Thereby, a remainder of a value divided by the operation value K can be obtained. The remainder operator 123 can also be implemented according to the above descriptions, though compared to the remainder operator 112, in the remainder operator 123 the first input terminal of the subtractor 310 is coupled to the output terminal of the adder 122, and the output terminal of the multiplexer 320 is coupled to the register 124.

The address generator 100 can be applied to a communication data coding/decoding circuit to perform data coding/decoding according to different transmission modes. FIG. 4 is a system block diagram of a communication data coding/decoding circuit according to an embodiment of the present invention. Referring to FIG. 4, the communication data coding/decoding circuit 400 includes an address generator 410, a memory bank 420, and a data encoder/decoder 430. The address generator 410 is similar to the address generator 100, and therefore detail descriptions thereof are not repeated. The memory bank 420 is coupled to the address generator 410 for outputting interleaved data (i.e. data to be coded/decoded) according to the address (i.e. the second operation result res2). The data encoder/decoder 430 is coupled to the memory bank 420 for coding/decoding the interleaved data.

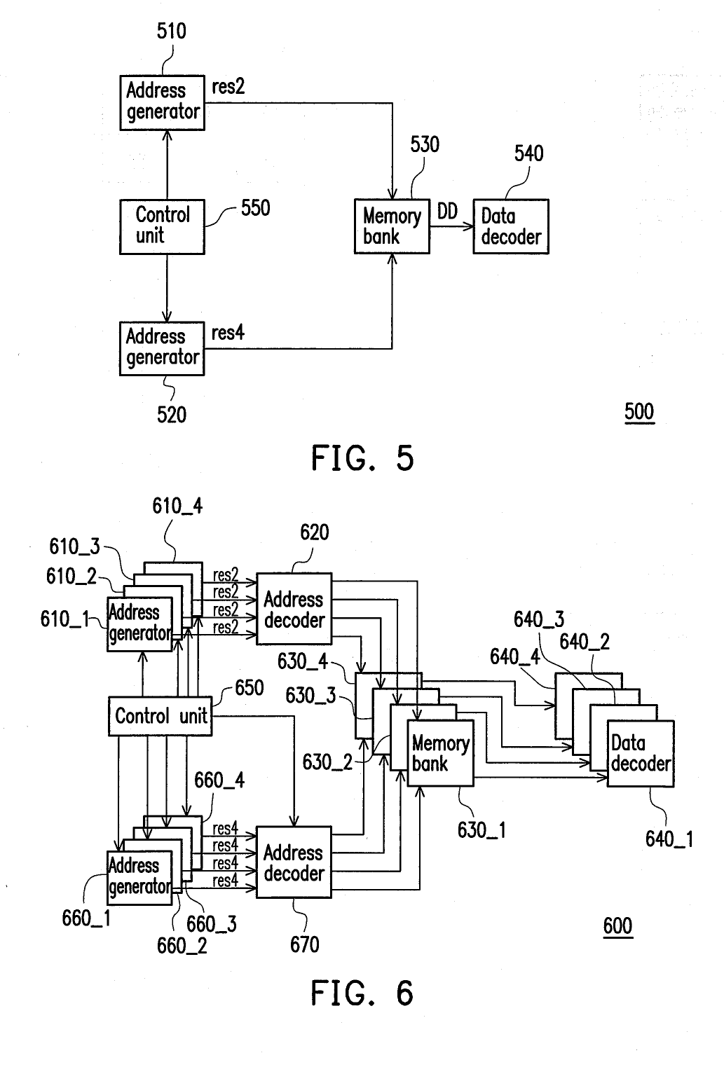

FIG. 5 is a system block diagram of a communication data decoding circuit integrated with single binary and double binary according to an embodiment of the present invention. Referring to FIG. 5, the communication data decoding circuit 500 includes address generators 510 and 520, a memory bank 530, a data decoder 540, and a control unit 550, wherein the data decoder 540 is, for example, a maximum A posterior (MAP) decoder. The address generators 510 and 520 are the same as the address generator 100, and therefore detail descriptions thereof are not repeated. Here, res2 is an operation result of the address generator 510, and res4 is an operation result of the address generator 520.

The memory bank 530 is coupled to the address generators 510 and 520 for outputting data DD to be decoded according to the operation results res2 and res4. The data decoder 540 is coupled to the memory bank 530 for decoding the data DD. The control unit 550 is coupled to the address generators 510 and 520 for providing parameters (for example, the initial value and the operation value) required by operations performed by the address generators 510 and 520.

First, taking the transmission mode of the WiMAX standard as an example, since the WiMAX standard is the double binary CTC, only one address generator (for example, the address generator 510) is required. If the transmission mode refers to the LTE standard of the single binary CTC, two address generators (for example, the address generators 510 and 520) have to be applied, so as to integrate the binary CTC and to use the same data decoder (for example, the data decoder 540).

When the transmission mode is the LTE standard, the address generator 520 is operated under control of the control unit 550. Since the address generators 510 and 520 are simultaneously operated, the address generators 510 and 520 can respectively output the operation result res2 and res4 when the original address i is an odd number and an even number, respectively, and therefore an increase by 1 in the incremental original address i can be changed to 2. For example, when the address generator 510 processes II(0), II(2), and II(4) . . . , the address generator 520 then processes II(1), II(3), and II(5) . . . . Here, the transmission mode signal represents a third mode, and the address generators 510 and 520 generate addresses according to a following equation:

Π(i+2)=[Π(i+1)+G(i+1)] mod K

A recursive formula can be deduced from the above equation, and a deduction process thereof is as follows:

$$\begin{matrix}Π ( i + 2 ) = [ Π ( i + 1 ) + G ( i + 1 ) ] mod K \\ = \{ [ Π ( i ) + G ( i ) ] + [ G ( i ) + 2 {f}_{2} ] \} mod K \\ = \{ Π ( i ) + [ 2 G ( i ) + 2 {f}_{2} ] \} mod K\end{matrix} \\ wherein , if H ( i ) = 2 G ( i ) + 2 {f}_{2} , then \text{:} \\ = [ Π ( i ) + H ( i ) ] mod K \qquad ( 13 )$$

Another recursive formula can also be deduced from the above function H(i), and a deduction process thereof is as follows:

$$\begin{matrix}H ( i + 2 ) = [ 2 G ( i + 2 ) + 2 {f}_{2} ] mod K \\ = \{ 2 [ G ( i + 1 ) + 2 {f}_{2} ] + 2 {f}_{2} \} mod K \\ = [ 2 G ( i + 1 ) + 6 {f}_{2} ] mod K \\ = [ 2 G ( i ) + 10 {f}_{2} ] mod K \\ = [ 2 H ( i ) + 8 {f}_{2} ] \} mod K\end{matrix} \qquad ( 14 )$$

As described above, when the transmission mode signal represents the third mode, the recursive operation performed by the first operation unit is H(i+2)=[H(i)+8f₂] mod K, wherein H(i) represents an i-th first operation result, f₂ is the first parameter, k is a constant, and mod is a remainder operator. Values of K, f₁, and f₂ can be obtained from the table 1. The recursive operation performed by the second operation unit is Π(i+2)=[Π(i)+H(i)] mod K, wherein II(i) represents an i-th second operation result res2. Moreover, the memory bank 530 outputs the data DD to be decoded according to the operation results res2 and res4.

Generally, to increase a decoding speed of the communication data decoding circuit and improve productivity, a plurality of data decoders is applied to achieve a parallel processing, and accordingly a plurality of the address generators is required to cope with said situation, wherein the number of the parallel processing is also referred to as a degree of parallelism. FIG. 6 is a system block diagram of a communication data decoding circuit according to another embodiment of the present invention. Referring to FIG. 6, the communication data decoding circuit 600 includes address generators 610_1-610_4 and 660_1-660_4, address decoders 620 and 670, memory banks 630_1-630_4, data decoders 640_1-640_4, and a control unit 650. The operation of the communication data decoding circuit 600 is similar to that of the communication data decoding circuit 500, and when the degree of parallelism of the data decoders is increased, the number of the memory banks is also increased to the same number of the data decoders. Therefore, the address decoders 620 and 670 are used for converting the outputs of the address generators into indicators of the memory banks, so that the data decoders may know where (a position in a certain memory bank) to read the data to be decoded.

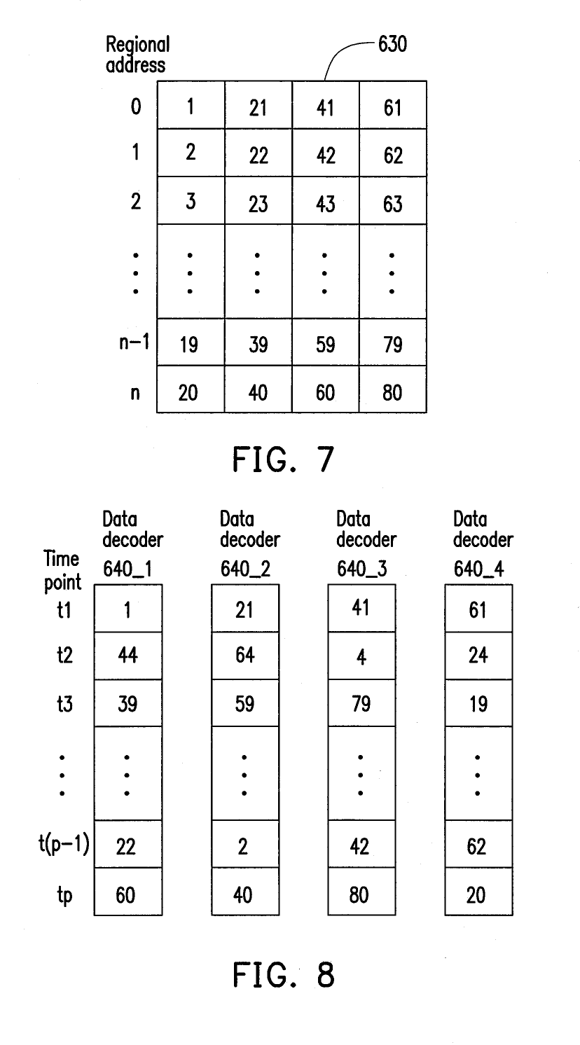

Since during the parallel processing, a problem of memory contention probably occurs, the degree of parallelism has to be properly set, so as to avoid the memory contention. Please refer to a table 3 and a table 4 for setting the properly degree of parallelism, wherein the transmission mode of the table 3 is LTE, the transmission mode of the table 4 is WiMAX, and Available P represents the suitable degree of parallelism. When the degree of parallelism is properly set, different data decoders (for example, 640_1-640_4) can capture the to-be-decoded data located at the same address in different memory banks, wherein the captured data are constituted by different data segments of the data to be decoded. The data to be decoded is composed of a plurality of data segments, and lengths of the data segments are different according to different designs. Therefore, arrangement of the data segments in the memory banks 630_1-630_4 can be made by integrating the memory banks into a single memory bank as shown in FIG. 7, the memory bank can output one vector (for example, 4, 24, 44, and 64) at one time according to the output parameters of the address decoders, and the output parameters of the address decoders can determine which value in the vector should be read by different data decoders.

TABLE 4

| K | Available P |
|---|---|
| 24 | 1 |
| 36 | 1 |
| 48 | 1 2 |
| 72 | 1 2 3 |
| 96 | 1 2 3 4 |
| 108 | 1 3 |
| 120 | 1 2 3 4 5 |
| 144 | 1 2 3 4 6 |
| 180 | 1 2 3 4 5 6 |
| 192 | 1 2 3 4 6 8 |
| 216 | 1 2 3 4 6 8 9 |
| 240 | 1 2 3 4 5 6 8 10 |
| 480 | 1 2 3 4 5 6 8 10 12 |
| 960 | 1 2 3 4 5 6 8 10 12 |
| 1440 | 1 2 3 4 5 6 8 9 10 12 |
| 1920 | 1 2 3 4 5 6 8 10 12 |
| 2400 | 1 2 3 4 5 6 8 10 12 |

TABLE 3

| K | Available P |
|---|---|
| 48 | 1 2 |
| 72 | 1 2 3 |
| 96 | 1 2 3 4 |
| 144 | 1 2 3 4 6 |
| 192 | 1 2 3 4 6 8 |
| 216 | 1 2 3 4 6 8 9 |
| 240 | 1 2 3 4 5 6 8 10 |
| 288 | 1 2 3 4 6 8 9 12 |
| 360 | 1 2 3 4 5 6 8 9 10 12 15 |
| 384 | 1 2 3 4 6 8 12 16 |
| 432 | 1 2 3 4 6 8 9 12 16 18 |
| 480 | 1 2 3 4 5 6 8 10 12 15 16 20 |
| 960 | 1 2 3 4 5 6 8 10 12 15 16 20 |
| 1920 | 1 2 3 4 5 6 8 10 12 15 16 20 |
| 2880 | 1 2 3 4 5 6 8 9 10 12 15 16 18 20 |
| 3840 | 1 2 3 4 5 6 8 10 12 15 16 20 |
| 4800 | 1 2 3 4 5 6 8 10 12 15 16 20 |

The data segments captured by the data decoders 640_1-640_4 are shown in FIG. 8. FIG. 8 is a schematic diagram illustrating interleaved data segments captured by the data decoders of FIG. 6. Referring to FIG. 7 and FIG. 8, when the address output by the address decoder is 2, the to-be-decoded data output by the memory bank 630 is vectors 2, 22, 42, and 62 which correspond to a time point t(p−1) of FIG. 8. The address decoder also outputs a vector address corresponding signal of [2 1 3 4], which represents that the data decoder 640_1 is supposed to capture the data 22, the data decoder 640_2 is supposed to capture the data 2, the data decoder 640_3 is supposed to capture the data 42, and the data decoder 640_4 is supposed to capture the data 62. Thereby, the memory banks 630_1-630_4 can be integrated into one single memory bank.

When the transmission mode is LTE, the address generators 610_1-610_4 and 660_1-660_4 are operated under the third mode, wherein the address generators 610_1-610_4 can sequentially output the second operation result res2, and the address generators 660_1-660_4 can sequentially output the fourth operation result res4. The address decoder 620 outputs a first address and a first vector address corresponding signal according to the received second operation result res2. The address decoder 670 outputs a second address and a second vector address corresponding signal according to the received fourth operation result res4. The memory bank 630 outputs the data to be decoded according to the first address, the first vector address corresponding signal, the second address, and the second vector address corresponding signal.

In summary, the operation units and the data decoders of different transmission modes are integrated into the address generator of the communication data interleaver and the communication data decoding circuit of the present invention. Moreover, in case of a proper degree of parallelism, the to-be-decoded data in the memory banks is integrated into a signal memory bank.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An address generator of a communication data interleaver, comprising:
a first operation unit having a first input terminal, a second input terminal, and an output terminal, wherein the first input terminal of the first operation unit receives a first parameter, and the second input terminal of the first operation unit is coupled to the output terminal of the first operation unit, so as to perform a recursive operation according to the first parameter and a first operation result and output the first operation result through the output terminal; and
a second operation unit having a first input terminal, a second input terminal, a third input terminal, and an output terminal, wherein the first input terminal of the second operation unit is coupled to the output terminal of the first operation unit, the second input terminal of the second operation unit receives a second parameter, and the third input terminal of the second operation unit is coupled to the output terminal of the second operation unit, so that according to a transmission mode signal, it is determined whether the second operation unit generates a second operation result by performing a recursive operation according to the first operation result, the second parameter, and the second operation result, or by calculating the first operation result and the second parameter.

2. The address generator of the communication data interleaver as claimed in claim 1, wherein when the transmission mode signal represents a first mode:
the recursive operation performed by the first operation unit is H(i+1)=[H(i)+2f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

3. The address generator of the communication data interleaver as claimed in claim 1, wherein when the transmission mode signal represents a second mode:
the recursive operation performed by the first operation unit is P(i+1)=[P(i)+P0], wherein P(i) represents an i-th first operation result, and P0 is the first parameter;
if i mod 4=0, the operation performed by the second operation unit is Π(i)=[P(i)+1] mod K, wherein II(i) represents an i-th second operation result, K is a constant, and mod is a remainder operator;
if i mod 4=1, the operation performed by the second operation unit is Π(i)=[P(i)+TP1] mod K, wherein the second parameter is TP1=1+K/2+P1, and K and P1 are constants;
if i mod 4=2, the operation performed by the second operation unit is Π(i)=[P(i)+TP2] mod K, wherein the second parameter is TP2=1+P2, and P2 is a constant; and
if i mod 4=3, the operation performed by the second operation unit is Π(i)=[P(i)+TP3] mod K, wherein the second parameter is TP3=1+K/2+P3, and P3 is a constant.

4. The address generator of the communication data interleaver as claimed in claim 1, wherein when the transmission mode signal represents a third mode:
the recursive operation performed by the first operation unit is H(i+2)=[H(i)+8f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

5. The address generator of the communication data interleaver as claimed in claim 1, wherein the first operation unit comprises:
a first adder having a first input terminal receiving the first parameter, and a second input terminal receiving the first operation result;
a first remainder operator coupled to an output terminal of the first adder for performing a remainder operation on an operation result of the first adder;
a first multiplexer having a first terminal coupled to an output terminal of the first remainder operator and a second terminal receiving an initial value for outputting the initial value or an operation result of the first remainder operator according to an initial signal; and
a first register storing an output of the first multiplexer and outputting stored data as the first operation result.

6. The address generator of the communication data interleaver as claimed in claim 5, wherein the first remainder operator comprises:
a first subtractor having a first input terminal coupled to the output terminal of the first adder and a second input terminal receiving an operation value for subtracting the operation value from the operation result of the first adder; and
a second multiplexer having a first terminal coupled to the output terminal of the first adder, a second terminal coupled to an output terminal of the first subtractor, and an output terminal coupled to the first terminal of the first multiplexer for outputting the operation result of the first adder or an operation result of the first subtractor according to the operation result of the first subtractor.

7. The address generator of the communication data interleaver as claimed in claim 1, wherein the second operation unit comprises:
a third multiplexer having a first terminal receiving the second operation result and a second terminal receiving the second parameter for outputting the second parameter or the second operation result according to the transmission mode signal;
a second adder having a first input terminal coupled to an output terminal of the third multiplexer and a second input terminal receiving the first operation result;
a second remainder operator coupled to an output terminal of the second adder for performing a remainder operation on an output of the second adder, so as to output an operation result; and
a second register storing the operation result of the second remainder operator and outputting stored data as the second operation result.

8. The address generator of the communication data interleaver as claimed in claim 7, wherein the second remainder operator comprises:
a second subtractor having a first input terminal coupled to the output terminal of the second adder and a second input terminal receiving an operation value for subtracting the operation value from the operation result of the second adder; and
a fourth multiplexer having a first terminal coupled to the output terminal of the second adder, a second terminal coupled to an output terminal of the second subtractor, and an output terminal coupled to the second register for outputting the operation result of the second adder or an operation result of the second subtractor according to the operation result of the second subtractor.

9. The address generator of the communication data interleaver as claimed in claim 1, further comprising:
a fifth multiplexer having a first terminal receiving a first reference value and a second terminal receiving a second reference value for outputting the first reference value or the second reference value as the first parameter according to the transmission mode signal.

10. The address generator of the communication data interleaver as claimed in claim 1, further comprising:
a sixth multiplexer having a first terminal receiving a first predetermined value, a second terminal coupled to a second predetermined value, a third terminal coupled to a third predetermined value, and a fourth terminal coupled to a fourth predetermined value for outputting the first predetermined value, the second predetermined value, the third predetermined value, or the fourth predetermined value as the second parameter according to a counting result.

11. The address generator of the communication data interleaver as claimed in claim 10, further comprising:
a counter coupled to the sixth multiplexer for outputting the counting result.

12. A communication data coding/decoding circuit, comprising:
a first address generator, comprising:
a first operation unit having a first input terminal, a second input terminal, and an output terminal, wherein the first input terminal of the first operation unit receives a first parameter, and the second input terminal of the first operation unit is coupled to the output terminal of the first operation unit, so as to perform a recursive operation according to the first parameter and output a first operation result; and
a second operation unit having a first input terminal, a second input terminal, a third input terminal, and an output terminal, wherein the first input terminal of the second operation unit is coupled to the output terminal of the first operation unit, the second input terminal of the second operation unit receives a second parameter, and the third input terminal of the second operation unit is coupled to the output terminal of the second operation unit, so that according to a transmission mode signal, it is determined whether the second operation unit generates a second operation result by performing a recursive operation according to the first operation result, the second parameter, and the second operation result, or by calculating the first operation result and the second parameter;
a memory bank coupled to the first address generator for outputting data to be coded/decoded according to the second operation result; and
a first data encoder/decoder coupled to the memory bank for coding/decoding the data to be coded/decoded.

13. The communication data coding/decoding circuit as claimed in claim 12, wherein when the transmission mode signal represents a first mode:
the recursive operation performed by the first operation unit is H(i+1)=[H(i)+2f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

14. The communication data coding/decoding circuit as claimed in claim 12, wherein when the transmission mode signal represents a second mode:
the recursive operation performed by the first operation unit is P(i+1)=[P(i)+P0], wherein P(i) represents an i-th first operation result, and P0 is the first parameter;
if i mod 4=0, the operation performed by the second operation unit is Π(i)=[P(i)+1] mod K, wherein II(i) represents an i-th second operation result, K is a constant, and mod is a remainder operator;
if i mod 4=1, the operation performed by the second operation unit is Π(i)=[P(i)+TP1] mod K, wherein the second parameter is TP1=1+K/2+P1, and K and P1 are constants;
if i mod 4=2, the operation performed by the second operation unit is Π(i)=[P(i)+TP2] mod K, wherein the second parameter is TP2=1+P2, and P2 is a constant; and
if i mod 4=3, the operation performed by the second operation unit is Π(i)=[P(i)+TP3] mod K, wherein the second parameter is TP3=1+K/2+P3, and P3 is a constant.

15. The communication data coding/decoding circuit as claimed in claim 12, wherein when the transmission mode signal represents a third mode:
the recursive operation performed by the first operation unit is H(i+2)=[H(i)+8f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

16. The communication data coding/decoding circuit as claimed in claim 12, further comprising:
a second address generator, comprising:
a third operation unit having a first input terminal, a second input terminal, and an output terminal, wherein the first input terminal of the third operation unit receives a third parameter, and the second input terminal of the third operation unit is coupled to the output terminal of the third operation unit, so as to perform a recursive operation according to the third parameter and output a third operation result; and
a fourth operation unit having a first input terminal, a second input terminal, a third input terminal, and an output terminal, wherein the first input terminal of the fourth operation unit is coupled to the output terminal of the third operation unit, the second input terminal of the fourth operation unit receives a fourth parameter, and the third input terminal of the fourth operation unit is coupled to the output terminal of the fourth operation unit, so that according to the transmission mode signal, it is determined whether the fourth operation unit generates a fourth operation result by performing a recursive operation according to the third operation result, or by calculating the third operation result and the fourth parameter; and
a controller coupled to the second address generator for determining whether the second address generator is operated according to the transmission mode signal.

17. The communication data coding/decoding circuit as claimed in claim 16, wherein when the transmission mode signal represents a third mode:
the recursive operation performed by the third operation unit is H(i+2)=[H(i)+8f₂] mod K, wherein H(i) represents an i-th third operation result, f₂ is the first parameter, K is a constant, and mod is a remainder operator; and
the recursive operation performed by the fourth operation unit is Π(i+1)=[Π(i)+H(i)] mod K, wherein II(i) represents an i-th fourth operation result.

18. The communication data coding/decoding circuit as claimed in claim 12, wherein the first operation unit comprises:
a first adder having a first input terminal receiving the first parameter and a second input terminal receiving the first operation result;
a first remainder operator coupled to an output terminal of the first adder for performing a remainder operation on an operation result of the first adder;
a first multiplexer having a first terminal coupled to an output terminal of the first remainder operator and a second terminal receiving an initial value for outputting the initial value or an operation result of the first remainder operator according to an initial signal; and
a first register storing an output of the first multiplexer and outputting stored data as the first operation result.

19. The communication data coding/decoding circuit as claimed in claim 18, wherein the first remainder operator comprises:
a first subtractor having a first input terminal coupled to the output terminal of the first adder and a second input terminal receiving an operation value for subtracting the operation value from the operation result of the first adder; and
a second multiplexer having a first terminal coupled to the output terminal of the first adder, a second terminal coupled to an output terminal of the first subtractor, and an output terminal coupled to the first terminal of the first multiplexer for outputting the operation result of the first adder or an operation result of the first subtractor according to the operation result of the first subtractor.

20. The communication data coding/decoding circuit as claimed in claim 12, wherein the second operation unit comprises:
a third multiplexer having a first terminal receiving the second operation result and a second terminal receiving the second parameter for outputting the second parameter or the second operation result according to the transmission mode signal;
a second adder having a first input terminal coupled to an output terminal of the third multiplexer and a second input terminal receiving the first operation result;
a second remainder operator coupled to an output terminal of the second adder for performing a remainder operation on the operation result of the second adder, so as to output the operation result; and
a second register storing the operation result of the second remainder operator and outputting stored data as the second operation result.

21. The communication data coding/decoding circuit as claimed in claim 20, wherein the second remainder operator comprises:
a second subtractor having a first input terminal coupled to the output terminal of the second adder and a second input terminal receiving an operation value for subtracting the operation value from the operation result of the second adder; and
a fourth multiplexer having a first terminal coupled to the output terminal of the second adder, a second terminal coupled to an output terminal of the second subtractor, and an output terminal coupled to the second register for outputting the operation result of the second adder or an operation result of the second subtractor according to the operation result of the second subtractor.

22. The communication data coding/decoding circuit as claimed in claim 12, wherein the first address generator further comprises:
a fifth multiplexer having a first terminal receiving a first reference value and a second terminal receiving a second reference value for outputting the first reference value or the second reference value as the first parameter according to the transmission mode signal.

23. The communication data coding/decoding circuit as claimed in claim 12, wherein the first address generator further comprises:
a sixth multiplexer having a first terminal receiving a first predetermined value, a second terminal coupled to a second predetermined value, a third terminal coupled to a third predetermined value, and a fourth terminal coupled to a fourth predetermined value for outputting the first predetermined value, the second predetermined value, the third predetermined value, or the fourth predetermined value as the second parameter according to a counting result.

24. The communication data coding/decoding circuit as claimed in claim 23, wherein the first address generator further comprises:
a counter coupled to the sixth multiplexer for outputting the counting result.

25. A communication data decoding circuit, comprising:
a plurality of first address generators, wherein each of the first address generators receives a first parameter and a second parameter, and according to a transmission mode signal, it is determined whether a second operation result is generated by performing a recursive operation according to the first parameter, or by calculating the first parameter and the second parameter;
a first address decoder coupled to the first address generators for generating a first address and a first vector address corresponding signal according to the second operation results;
a memory bank coupled to the first address decoder for outputting data to be decoded according to the first address and the first vector address corresponding signal, wherein the data to be decoded has a plurality of data segments; and
a plurality of data decoders coupled to the memory bank, the data decoders respectively capturing the corresponding data segment in the data to be decoded according to the first vector address corresponding signal, so as to decode the captured data segment.

26. The communication data decoding circuit as claimed in claim 25, wherein the first address generator comprises:
a first operation unit having a first input terminal, a second input terminal, and an output terminal, wherein the first input terminal of the first operation unit receives a first parameter, and the second input terminal of the first operation unit is coupled to the output terminal of the first operation unit, so as to perform a recursive operation according to the first parameter and output a first operation result; and
a second operation unit having a first input terminal, a second input terminal, a third input terminal, and an output terminal, wherein the first input terminal of the second operation unit is coupled to the output terminal of the first operation unit, the second input terminal of the second operation unit receives a second parameter, and the third input terminal of the second operation unit is coupled to the output terminal of the second operation unit, so that according to the transmission mode signal, it is determined whether the second operation unit generates a second operation result by performing a recursive operation according to the first operation result, or by calculating the first operation result and the second parameter.

27. The communication data decoding circuit as claimed in claim 26, wherein when the transmission mode signal represents a first mode:
the recursive operation performed by the first operation unit is H(i+1)=[H(i)+2f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

28. The communication data decoding circuit as claimed in claim 26, wherein when the transmission mode signal represents a second mode:
the recursive operation performed by the first operation unit is P(i+1)=[P(i)+P0], wherein P(i) represents an i-th first operation result, and P0 is the first parameter;
if i mod 4=0, the operation performed by the second operation unit is Π(i)=[P(i)+1] mod K, wherein II(i) represents an i-th second operation result, K is a constant, and mod is a remainder operator;
if i mod 4=1, the operation performed by the second operation unit is Π(i)=[P(i)+TP1] mod K, wherein the second parameter is TP1=1+K/2+P1, and K and P1 are constants;
if i mod 4=2, the operation performed by the second operation unit is Π(i)=[P(i)+TP2] mod K, wherein the second parameter is TP2=1+P2, and P2 is a constant; and
if i mod 4=3, the operation performed by the second operation unit is Π(i)=[P(i)+TP3] mod K, wherein the second parameter is TP3=1+K/2+P3, and P3 is a constant.

29. The communication data decoding circuit as claimed in claim 26, wherein when the transmission mode signal represents a third mode:
the recursive operation performed by the first operation unit is H(i+2)=[H(i)+8f₂] mod K, wherein H(i) represents an i-th first operation result, f₂ is the first parameter, K is a constant, and mod is a remainder operator; and
the recursive operation performed by the second operation unit is Π(i+1)=[Π(i)+H(i)] mod K, wherein II(i) represents an i-th second operation result.

30. The communication data decoding circuit as claimed in claim 26, wherein the first operation unit comprises:
a first adder having a first input terminal receiving the first parameter and a second input terminal receiving the first operation result;
a first remainder operator coupled to an output terminal of the first adder for performing a remainder operation on an operation result of the first adder;
a first multiplexer having a first terminal coupled to an output terminal of the first remainder operator and a second terminal receiving an initial value for outputting the initial value or an operation result of the first remainder operator according to an initial signal; and
a first register storing an output of the first multiplexer and outputting stored data as the first operation result.

31. The communication data decoding circuit as claimed in claim 30, wherein the first remainder operator comprises:
a first subtractor having a first input terminal coupled to the output terminal of the first adder and a second input terminal receiving an operation value for subtracting the operation value from the operation result of the first adder; and
a second multiplexer having a first terminal coupled to the output terminal of the first adder, a second terminal coupled to an output terminal of the first subtractor, and an output terminal coupled to the first terminal of the first multiplexer for outputting the operation result of the first adder or an operation result of the first subtractor according to the operation result of the first subtractor.

32. The communication data decoding circuit as claimed in claim 30, wherein the second operation unit comprises:
a third multiplexer having a first terminal receiving the second operation result and a second terminal receiving the second parameter for outputting the second parameter or the second operation result according to the transmission mode signal;
a second adder having a first input terminal coupled to an output terminal of the third multiplexer and a second input terminal receiving the first operation result;
a second remainder operator coupled to an output terminal of the second adder for performing a remainder operation on the operation result of the second adder, so as to output the operation result; and
a second register storing the operation result of the second remainder operator and outputting stored data as the second operation result.

33. The communication data decoding circuit as claimed in claim 32, wherein the second remainder operator comprises:
a second subtractor having a first input terminal coupled to the output terminal of the second adder and a second input terminal receiving an operation value for subtracting the operation value from the operation result of the second adder; and
a fourth multiplexer having a first terminal coupled to the output terminal of the second adder, a second terminal coupled to an output terminal of the second subtractor, and an output terminal coupled to the second register for outputting the operation result of the second adder or an operation result of the second subtractor according to the operation result of the second subtractor.

34. The communication data decoding circuit as claimed in claim 26, wherein each of the first address generators further comprises:
a fifth multiplexer having a first terminal receiving a first reference value and a second terminal receiving a second reference value for outputting the first reference value or the second reference value as the first parameter according to the transmission mode signal.

35. The communication data decoding circuit as claimed in claim 26, wherein each of the first address generators further comprises:
a sixth multiplexer having a first terminal receiving a first predetermined value, a second terminal coupled to a second predetermined value, a third terminal coupled to a third predetermined value, and a fourth terminal coupled to a fourth predetermined value for outputting the first predetermined value, the second predetermined value, the third predetermined value, or the fourth predetermined value as the second parameter according to a counting result.

36. The communication data decoding circuit as claimed in claim 35, wherein the first address generator further comprises:
a counter coupled to the sixth multiplexer for outputting the counting result.

37. The communication data decoding circuit as claimed in claim 25, further comprising:
a plurality of second address generators, wherein each of the second address generators receives a third parameter and a fourth parameter, and according to the transmission mode signal, it is determined whether a fourth operation result is generated by performing a recursive operation according to the third parameter, or by calculating the third parameter and the fourth parameter;
a second address decoder coupled to the second address generators for generating a second address and a second vector address corresponding signal according to the fourth operation results; and
a controller coupled to the second address generators and the second address decoder for controlling operations of the second address generators and the second address decoder according to the transmission mode signal,
wherein the memory bank is coupled to the second address decoder for outputting data to be decoded according to the second address and the second vector address corresponding signal, and the data decoders capture the corresponding data segments in the data to be decoded according to the second vector address corresponding signal.

38. The communication data decoding circuit as claimed in claim 25, wherein each of the second address generators comprises:
a third operation unit having a first input terminal, a second input terminal, and an output terminal, wherein the first input terminal of the third operation unit receives a third parameter, and the second input terminal of the third operation unit is coupled to the output terminal of the third operation unit, so as to perform a recursive operation according to the third parameter and output a third operation result; and
a fourth operation unit having a first input terminal, a second input terminal, a third input terminal, and an output terminal, wherein the first input terminal of the fourth operation unit is coupled to the output terminal of the third operation unit, the second input terminal of the fourth operation unit receives a fourth parameter, and the third input terminal of the fourth operation unit is coupled to the output terminal of the fourth operation unit, so that according to the transmission mode signal, it is determined whether the fourth operation unit generates the fourth operation result by performing a recursive operation according to the third operation result, or by calculating the third operation result and the fourth parameter.

39. The communication data decoding circuit as claimed in claim 38, wherein when the transmission mode signal represents a third mode:
the recursive operation performed by the third operation unit is H(i+2)=[H(i)+8f₂] mod K, wherein H(i) represents an i-th third operation result, f₂ is the first parameter, K is a constant, and mod is a remainder operator; and
the recursive operation performed by the fourth operation unit is Π(i+1)=[Π(i)+H(i)] mod K, wherein II(i) represents an i-th fourth operation result.
